(19) United States
(12) Patent Application Publication
(10) Pub. No.: US 2025/0338062 A1
(43) Pub. Date: Oct. 30, 2025

(54) SYSTEM AND METHOD FOR AUDIO SYNTHESIS USING FIELD PROGRAMMABLE GATE ARRAYS

(71) Applicant: Differential Audio Inc., Manotick (CA)

(72) Inventor: Frederick Robert Eric Dyer, Manotick (CA)

(73) Assignee: Differential Audio Inc., Manotick (CA)

(21) Appl. No.: 19/096,303

(22) Filed: Mar. 31, 2025

Related U.S. Application Data
(60) Provisional application No. 63/640,169, filed on Apr. 29, 2024.

(51) Int. Cl. H04R 3/00; H03K 19/177

(52) U.S. Cl. CPC H04R 3/00; H03K 19/177

(57) ABSTRACT

What is disclosed is: A method to generate audio output signals, wherein: a control subsystem is communicatively coupled to a waveform subsystem, further wherein the waveform subsystem is implemented using field programmable gate arrays (FPGAs); the method comprising: responsive to a trigger signal, transmitting, by the waveform subsystem, read requests to retrieve a plurality of descriptors from the control subsystem; transmitting, by the control subsystem to the waveform subsystem, the retrieved plurality of descriptors; generating an additive oscillator, wherein the additive oscillator is generated based on a plurality of partial oscillators, and the plurality of partial oscillators is generated based on the transmitted plurality of descriptors; and generating audio output signals based on the generated audio output channel.

### CROSS-REFERENCE TO RELATED APPLICATIONS

The instant application claims priority to U.S. provisional application 63/640,169, filed on Apr. 29, 2024, presently pending. The contents of this application are hereby incorporated by reference.

### FIELD OF THE INVENTION

The present disclosure relates to synthesis of audio signals using field programmable gate arrays (FPGA).

### BRIEF SUMMARY

A system to generate audio output signals comprising: a control subsystem coupled to a waveform subsystem via one or more first interconnections, wherein: the control subsystem comprises a control subsystem storage storing one or more descriptor tables; the waveform subsystem is implemented using field programmable gate arrays (FPGAs), wherein the waveform subsystem comprises: an oscillator generation subsystem, a waveform read subsystem, and an output interface, further wherein: the oscillator generation subsystem, the waveform read subsystem and the output interface are communicatively coupled to each other via waveform subsystem interconnections; the control subsystem generates and transmits a trigger signal to the waveform read control subsystem; in response to the transmitted trigger signal, the waveform read control subsystem transmits read requests to the control subsystem storage to retrieve a plurality of descriptors stored in the descriptor tables via the first set of interconnections; based on the transmitted read requests, the plurality of descriptors are: retrieved from the control subsystem storage, and transmitted to the oscillator generation subsystem via the first set of interconnections; the oscillator generation subsystem: generates an additive oscillator, further wherein: the additive oscillator is generated based on a plurality of partial oscillators, and the plurality of partial oscillators is generated based on the transmitted plurality of descriptors, and transmits the generated additive oscillator to the output interface via an audio channel; and the output interface receives the transmitted additive oscillator and generates the audio output signals based on the received additive oscillator.

A method to generate audio output signals, wherein: a control subsystem is communicatively coupled to a waveform subsystem, further wherein the waveform subsystem is implemented using field programmable gate arrays (FPGAs); the method comprising: responsive to a trigger signal, transmitting, by the waveform subsystem, read requests to retrieve a plurality of descriptors from the control subsystem; transmitting, by the control subsystem to the waveform subsystem, the retrieved plurality of descriptors; generating an additive oscillator, wherein the additive oscillator is generated based on a plurality of partial oscillators, and the plurality of partial oscillators is generated based on the transmitted plurality of descriptors; and generating audio output signals based on the generated audio output channel.

The foregoing and additional aspects and embodiments of the present disclosure will be apparent to those of ordinary skill in the art in view of the detailed description of various embodiments and/or aspects, which is made with reference to the drawings, a brief description of which is provided next.

### BRIEF DESCRIPTION OF THE DRAWINGS

The foregoing and other advantages of the disclosure will become apparent upon reading the following detailed description and upon reference to the drawings.

FIG. 1 illustrates an example embodiment of a system for audio synthesis.

FIG. 2 illustrates an example embodiment of a waveform subsystem.

FIG. 2B illustrates an example embodiment of an additive oscillator.

FIG. 2C illustrates an example embodiment of an additive oscillator generation unit.

FIG. 3 illustrates an example embodiment of a control subsystem.

FIG. 4 illustrates an example embodiment of a display of timelines on a graphical user interface.

FIG. 5 illustrates an example embodiment of a display of partial parameter curves on a graphical user interface.

FIG. 6 illustrates an example embodiment of a display of an amplitude envelope.

FIG. 7 illustrates an example embodiment of a process to create and display a partial parameter envelope.

FIG. 8 illustrates an example embodiment of a process to produce audio output signals using read data from a descriptor table.

FIG. 9 illustrates an example embodiment of a process for additive resynthesis.

FIG. 10 illustrates an example embodiment of a process to generate an additive oscillator for transmission over an audio channel.

While the present disclosure is susceptible to various modifications and alternative forms, specific embodiments or implementations have been shown by way of example in the drawings and will be described in detail herein. It should be understood, however, that the disclosure is not intended to be limited to the particular forms disclosed. Rather, the disclosure is to cover all modifications, equivalents, and alternatives falling within the spirit and scope of an invention as defined by the appended claims.

### DETAILED DESCRIPTION

Additive synthesis is a sound synthesis technique, wherein sums of sinusoids or partials are used to create audio signals. Additive synthesis has the advantage that the many micro-variations in the frequency and amplitude of the individual partials which make natural sounds so rich and lively can be recreated.

Since each audio signal is built “from the ground up”, additive synthesis offers a lot of flexibility when compared to other techniques such as subtractive synthesis. In subtractive synthesis, frequency content of an already existing audio signal is attenuated using, for example, a low-pass filter. Specifically, low-pass filtering is applied to a complex time signal such as a square or sawtooth wave, which has harmonic content at fixed integer multiples of a fundamental frequency. Additive synthesis on the other hand is not limited to fixed integer multiple frequency content. Then, the flexibility to create sounds is limited in subtractive synthesis when compared to additive synthesis. Allowing for partial frequencies to be based on non-integer multiples of the fundamental may result in timbres that cannot be generated using subtractive synthesizers.

Additive synthesis often requires many oscillators to produce good quality sound, which can be computationally demanding. Prior use solutions have been demonstrated before, such as:
the RMI Harmonic Synthesizer;
the Fairlight Computer Musical Instrument (CMI);
the New England Digital Synclavier II;
the Kawai K5 m;
the Wersi EX20; and
the Technos Acxel.
   However, many of these additive synthesizers suffered from major limitations: Computation capability was limited, and control was complicated and tedious for the end user.

Solutions based on Field Programmable Gate Arrays (FPGAs) can help reduce the computational limitations. Solutions which use customized FPGAs can implement a far greater number of computations per second compared to software implementation on a generic processor. Specifically, these FPGA-based solutions provide large parallel computational capacity with low latency and high memory bandwidth compared to traditional implementations which use, for example, a combination of software and a microprocessor.

A demonstration of the enhanced parallel computational capacity of FPGA-based solutions is provided in, for example, Herbordt, M. C., VanCourt, T., G u, Y., Sukhwani, B., Conti, A., Model, J. and DiSabello, D., 2007. Achieving high performance with FPGA-based computing. Computer, 40(3), pp. 50-57, hereinafter referred to as the “Herbordt reference” and included in Appendix A of U.S. provisional application 63/640,169. As explained in the Herbordt reference, a thousand-fold parallelism is possible with FPGA-based solutions.

A further demonstration of the enhanced computational capacity of FPGA-based solutions is provided in Sundararajan, P., Sep. 10, 2010. High performance computing using FPGAs (pp. 1-15). Technical Report, hereinafter referred to as the “Sundararajan reference” and included in Appendix B of U.S. provisional application 63/640,169. As was explained in the Sundararajan reference: “The FPGA architecture provides the flexibility to create a massive array of application-specific ALUs that enable both instruction and data-level parallelism. Because data flows between operators, there are no inefficiencies like processor cache misses; FPGA data can be streamed between operators. These operators can be configured to have point-to-point dedicated interconnects, thereby efficiently pipelining the execution of operators.”

From the point of view of additive synthesis, using FPGA-based solutions allows for more parallel computations. For example, many partial oscillators can be modified using several parameters in real time.

Software implementations rely on buffering several samples before processing these in order to gain efficiency, leading to longer latency, wherelse FPGA implementations are more amenable to a pipelined implementation and per sample computation.

Another implementation approach is by using application specific integrated circuit (ASIC)-based approaches. However, ASIC configurations are fixed by design when manufactured, whereas FPGA-based approaches are programmable. Specifically, FPGA-based approaches can be programmed from boot code at power up, meaning that these solutions can be updated in the field with firmware updates that will be sent out to the user. Therefore FPGA-based approaches offer flexibility compared to ASIC-based approaches.

The prior art does not address the problems of computational complexity, and complicated control for the user. Neither does the prior art contain detailed descriptions of how FPGAs can be used to implement additive synthesizers. For example, U.S. Pat. No. 11,348,595 to Hetherington et al, which was filed 7 Dec. 2017, published 31 May 2022, and is hereinafter referred to as the “Hetherington reference”; describes use of subtractive synthesis and/or additive synthesis in real-time to dynamically reshape sound based on a changing audio environment that can occur within a vehicle's cabin. While the Hetherington reference contemplates the use of FPGAs, it does not specify how FPGAs can be used to implement additive synthesizers.

U.S. Pat. No. 8,653,354 to van Buskirk et al, which was filed 2 Aug. 2011, published 18 Feb. 2014, and is hereinafter referred to as the “van Buskirk reference”; describes systems and methods to synthesize audio. The van Buskirk reference allows specification of a musical sound to be generated. The van Buskirk reference describes synthesizing an audio source, such as noise, using parameters to specify the desired frequency slit spacing and the desired noise-to-frequency band ratio, then filtering the audio source through a sequence of filters to obtain the desired frequency slit spacing and noise to frequency band ratio. The van Buskirk reference describes modulation of the filters in the sequence, and the output of musical sound. However, the van Buskirk reference teaches away from additive synthesis. According to the van Buskirk reference, additive synthesis “does not have the ability to produce realistic noise components nor has it the ability for complex noise interactions, as is desirable for many types of musical sounds.” The van Buskirk reference does not mention FPGAs, and therefore does not describe how FPGAs can be used to implement additive synthesizers. Furthermore, since signals are built from the ground up with additive synthesis, filters are not required to modify the quality of a sound.

Prior art processes to perform resynthesis also suffer from shortcomings. Software-based approaches such as the Sinusoidal Partial Editing Analysis and Resynthesis (SPEAR) software application described in Klingbeil M. “Software for spectral analysis, editing, and synthesis” in ICMC 2005 September, hereinafter referred to as the “Klingbeil reference”; are limited to using hundreds of partial oscillators for operation in real-time. This reduces the resynthesis capability when compared to an FPGA implementation.

There is a need for systems and methods which:
Enable simplified entry of large amounts of control data to make additive synthesizers more user friendly;
Enable manipulation of amplitude, frequency, amplitude modulation (AM) and frequency modulation (FM) parameters over time for partial oscillators of an additive oscillator;
Utilize FPGAs to improve computational capabilities;
Enable real-time fine resolution spectral resynthesis, wherein a reference audio signal can be rebuilt from thousands of constituent frequencies in real-time.

The following details systems and methods for audio synthesis which overcomes the shortcomings posed by the prior art and prior use solutions described above, and addresses the needs outlined above.

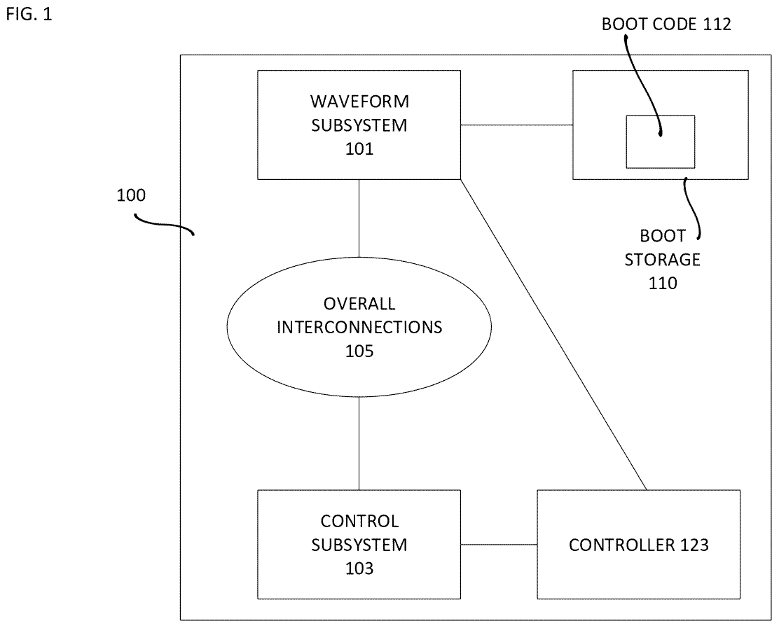

FIG. 1 shows an example embodiment of a system 100 for audio synthesis. System 100 comprises a waveform subsystem 101, control subsystem 103, and overall interconnections 105. Overall interconnections 105 communicatively couples the components of waveform subsystem 101 to the components of control subsystem 103 as needed, and are discussed in detail further below. This enables the components of waveform subsystem 101 to transmit and receive data, commands and instructions to and from the components of control subsystem 103. Controller 123 is communicatively coupled to control subsystem 103. This is achieved by, for example, a wired or a wireless connection. Technologies to implement such communicative coupling are known to those of ordinary skill in the art.

Controller 123 plays the role of transmitting signals such as commands and triggers to the control subsystem 103. Examples of commands and triggers include, but are not limited to, MIDI Note On and MIDI Note Off commands and triggers. In some embodiments, controller 123 is a Musical Instrument Digital Interface (MIDI) controller. In these embodiments, controller 123 sends MIDI commands and triggers. In some embodiments, controller 123 is implemented using hardware. In other embodiments, controller 123 is implemented using software. In yet other embodiments, controller 123 is implemented using a combination of hardware and software.

In some embodiments, the commands and triggers have one or more associated status fields. For example, the MIDI Note On command has a status field called velocity. This indicates the speed in which a musician strikes a note on the controller. For example, when playing a piano, there is a very audible difference between striking a key quickly and hard, and striking slow and gently. This information is encapsulated in the MIDI Note On command velocity field.

Another example of a status field is the MIDI Channel Number that the command is associated with. Then, in some embodiments, a patch is associated with that channel. A patch is a polyphony of a hierarchy of multiple sounds, where each sound is comprised of one or more oscillators, and associated with descriptor tables. In some embodiments, a patch is a type of instrument, for example, violins or trumpets. Then, in some embodiments, the patch is polyphonic, that is, there are, for example, multiple violins or multiple trumpets. Based on the information in the command, triggers are sent to the waveform read control subsystem 305, which then issues read requests for the descriptors to the corresponding oscillators.

The controller 123 also sends other information within commands and triggers. An example of this other information is aftertouch information. Aftertouch information indicates how hard the user is pressing a key during the note. The aftertouch information is sent continuously from the controller 123, and this information is used by the waveform read control subsystem 305 to update modifier control variables that update the read descriptor data values which is sent on to the additive oscillators, that is, the read descriptor data is scaled by the aftertouch modifiers multiplied by an aftertouch modifier sensitivity.

In yet other embodiments, controller 123 is also communicatively coupled to waveform subsystem 101. Technologies and techniques to implement this communicative coupling, such as wired or wireless communication technologies, are known to those of ordinary skill in the art.

In some embodiments, control subsystem 103 is co-located together with waveform subsystem 101. An example of such an embodiment is where control subsystem 103 is stored on a processor that co-ordinates the operations of waveform subsystem 101, such as waveform subsystem processor 317. An example of this arrangement is provided in the FS-256 Additive Synthesizer User Manual (DRAFT), Differential Audio Inc., Mar. 7, 2024, which was included in Appendix D of U.S. provisional application 63/640,169, filed on Apr. 29, 2024 and hereinafter referred to as “the Draft User Manual”. FIG. 1 on Page 9 as well as Section 3 from pages 9-11 of the Draft User Manual show example embodiments.

In some embodiments, control subsystem 103 and waveform subsystem 101 are on different devices. For example, control subsystem 103 is located on a device such as a laptop, smartphone or tablet; while waveform subsystem 101 is located on a different device communicatively coupled to the device such as the laptop, smartphone or tablet comprising the control subsystem 103.

In some embodiments, control subsystem 103 is implemented using hardware. In yet other embodiments, control subsystem 103 is implemented using software. In yet other embodiments, control subsystem 103 is implemented using a combination of hardware and software. In some of the embodiments where control subsystem 103 is implemented in hardware, control subsystem 103 is implemented using FPGAs. In some of the embodiments where control subsystem 103 is implemented using FPGAs, control subsystem storage 211 is implemented using embedded software.

In some embodiments, overall interconnections 105 are implemented using communications technologies known to those in the art. Examples of these communications technologies comprise:
On-chip communication bus protocols, such as protocols which form part of the Advanced Microcontroller Bus Architecture (AMBA) specification. An example protocol is the Advanced eXtensible Interface protocol;
Wired communications technologies such as cables, and Universal Serial Bus (USB) connections; and
Wireless communication technologies.

Waveform subsystem 101 produces signal outputs, which are discussed in further detail below. In some embodiments, waveform subsystem 101 is implemented using FPGAs. An example of an FPGA technology which can be used is the XILINX® ZYNQ SOC FPGA. As explained previously, using FPGAs can result in far enhanced parallel computational capability, which addresses the computational capability drawbacks of the prior art systems. As explained previously, FPGA-based solutions can be programmed from boot code at power up. In some embodiments and referring to FIG. 1 this is achieved using boot code 112 which is stored on boot storage 110. Boot storage 110 is communicatively coupled to waveform subsystem 101 using, for example, a wired or a wireless connection.

Boot storage 110 is implemented using storage hardware known to one of skill in the art. In some embodiments, boot storage 110 is implemented using a Secure Digital (SD) card. Then, firmware updates to boot code 112 that are sent to the user can be loaded onto boot storage 110. In some embodiments, the SD card is a microSD card. In some of these embodiments, an appropriate adapter such as a microSD to full SD card adapter or microSD to USB adapter is used when a microSD card slot is not available.

In other embodiments, firmware updates are performed using USB. This enables use of, for example, a USB flash drive to update boot code 112. In yet other embodiments, the SD card appears as an external storage device coupled to the boot storage 110 via USB. As explained before, this provides FPGA-based solutions with flexibility compared to ASIC-based solutions, as previously discussed.

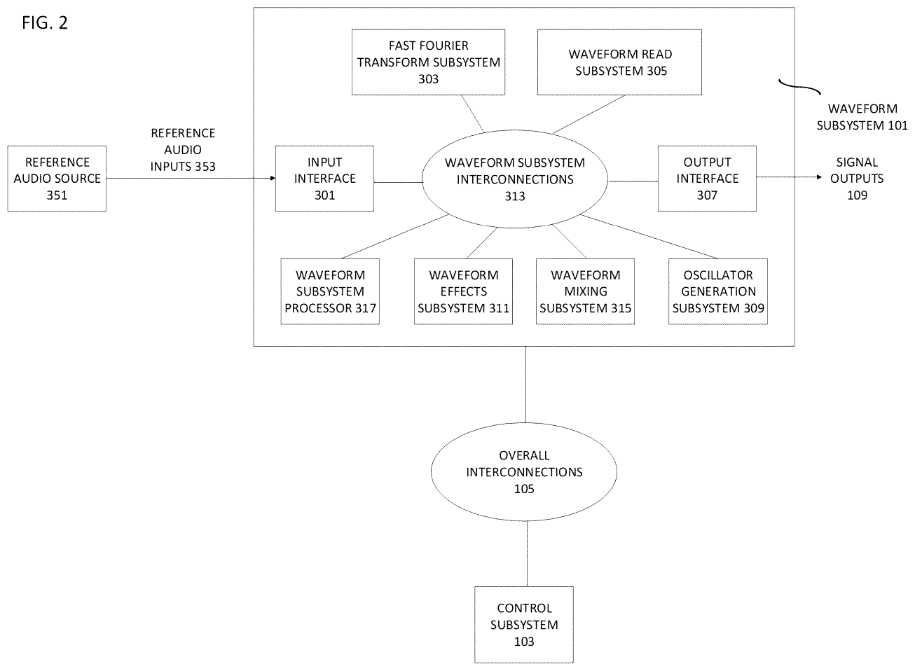

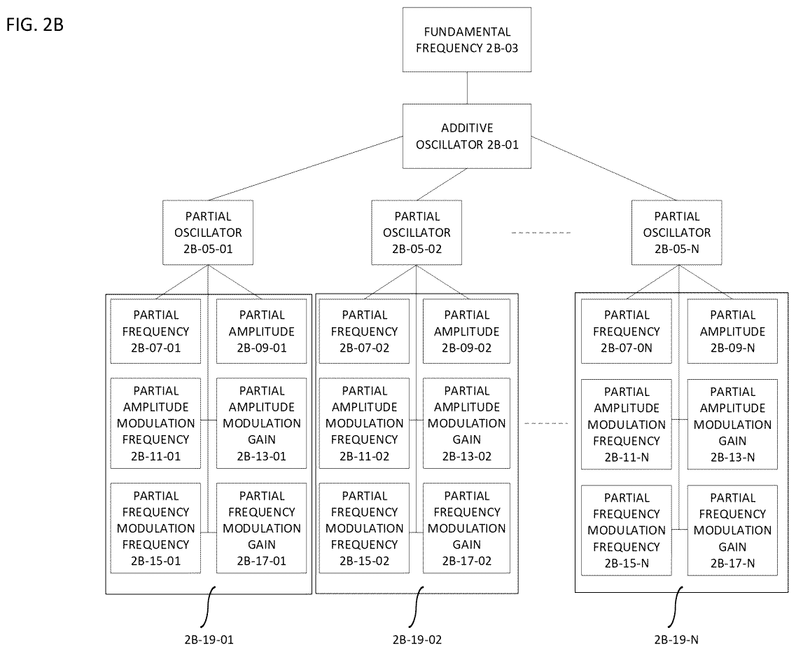

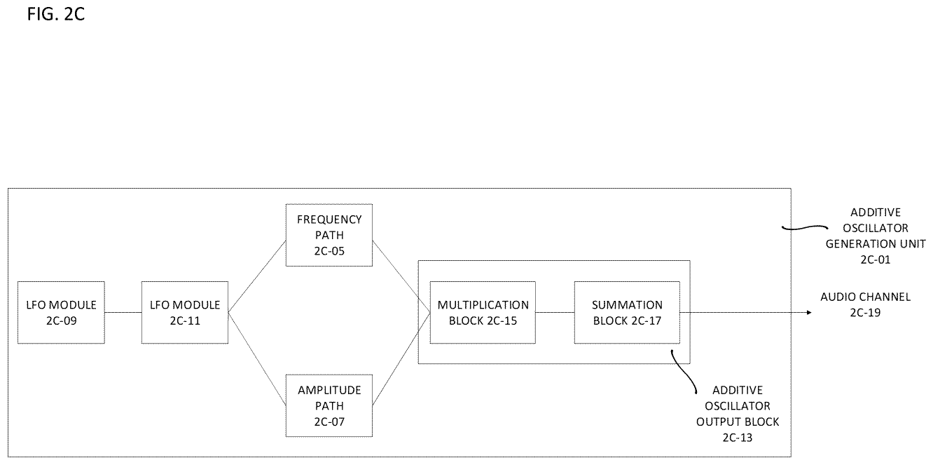

A detailed embodiment of waveform subsystem 101 is shown in FIG. 2. As explained above, waveform subsystem 101 produces signal outputs, such as signal outputs 109 in FIG. 2. Signal outputs 109 are generated in one or more ways. In some embodiments, signal outputs 109 are generated based on user inputs supplied to control subsystem 103, as is detailed below. In other embodiments, signal outputs 109 are generated based on reference audio inputs 353, as is detailed below. In the embodiment shown in FIG. 2, waveform subsystem 101 comprises input interface 301, Fast Fourier Transform (FFT) subsystem 303, waveform read control subsystem 305, output interface 307, oscillator generation subsystem 309, waveform subsystem interconnections 313, waveform mixing subsystem 315, waveform effects subsystem 311 and waveform subsystem processor 317.

Input interface 301 acts to receive reference audio inputs 353 from reference audio source 351.

In some embodiments, reference audio source 351 is a device which is external to waveform subsystem 101, and which outputs audio as electronic signals. The external device is communicatively coupled to input interface 301 via:
a wireless connection e.g. a BLUETOOTH® connection or a Wi-Fi connection, or
a wired connection such as an audio cable or a USB connection.

Examples of such an external device are:
an audio interface box,
a microphone,
a portable audio player,
a synthesizer,
a smartphone,
a tablet,
a laptop computer, or
a desktop computer,
which is communicatively coupled to input interface 301 via a wireless or wired connection.

In other embodiments, reference audio source 351 is internal to waveform subsystem 101. Examples include storage media such as SD cards. Then, reference audio source 351 stores audio as data files formatted according to an appropriate format such as Motion Pictures Expert Group-2 Audio Layer III (MP3), Advanced Audio Coding (AAC), Waveform Audio File Format (WAV) and so on. Reference audio source 351 outputs these files to input interface 301.

In other embodiments, reference audio source 351 outputs audio as sound waves. Examples are:
One or more live voices,
One or more live musical instruments,
One or more recorded voices,
One or more recorded musical instruments,
which are within listening range of input interface 301.

Reference audio inputs 353 comprise audio which is outputted by the reference audio source 351. These audio inputs comprise, for example:
wireless or wired signals transmitted via the previously mentioned wireless or wired connections between reference audio source 351 and input interface 301;
data files in the cases where reference audio source 351 is internal; or
sound waves transmitted “over the air” by reference audio source 351.

Reference audio inputs 353 are in either analog or digital format. In embodiments where reference audio inputs 353 are in analog, these inputs must be converted to digital before being transmitted to the rest of waveform subsystem 101. This analog-to-digital conversion is performed in the input interface 301 as will be explained below.

Input interface 301 comprises one or more input receiving devices and implements one or more technologies known to those of skill in the art, to perform the role of receiving reference audio inputs 353. Examples of such input receiving devices comprise microphones, BLUETOOTH® receivers, input ports, Line In ports, Analog In ports, and audio jacks which are compliant with standards necessary to receive and capture audio in either electronic or sound format.

In some embodiments, input interface 301 plays the role of appropriately formatting received reference audio inputs 353 for further processing within waveform subsystem 101. In some embodiments, this formatting comprises converting reference audio inputs 353 from analog to digital. Then, in these embodiments, the input interface 301 comprises one or more analog-to-digital converters (ADCs) so as to convert reference audio inputs 353 which are in analog into digital, before transmitting the digital signals to the waveform subsystem interconnections 313. In some embodiments, input interface 301 outputs digital signals over audio channels with a fixed bit rate and a fixed audio sample rate.

Waveform subsystem interconnections 313 plays the role of communicatively coupling different components of waveform subsystem 101 to enable digital signals to be routed from one component to another component. In some embodiments, waveform subsystem interconnections 313 implements time division multiplexing (TDM) to route digital signals over channels between components. In yet other embodiments, waveform subsystem interconnections 313 comprises appropriate bus technologies. Further details of embodiments of the waveform subsystem interconnections 313 are provided in, for example, section 5.3 which is in pages 19 and 20 of the Draft User Manual. In some embodiments, the waveform subsystem interconnections 313 contains a plurality of time division multiplexed channels, comprising, for example:
one channel for each of the plurality of additive oscillators,
channels for outputs from the waveform effects subsystem 311,
channels for outputs from the waveform mixing subsystem 315,
channels for the controller 123 in embodiments where the controller 123 is coupled to the waveform subsystem 101, and
channels for the input interface 301.

In some embodiments, the received reference audio inputs 353 are used for resynthesis. In these embodiments, FFT subsystem 303 receives signals from the input interface 301 via waveform subsystem interconnections 313, and analyzes these received signal inputs to determine the frequency components of the received signal inputs. FFT subsystem 303 performs this, using one or more FFT techniques known to those of skill in the art. In some embodiments, FFT subsystem 303 is based on the XILINX FFT LogiCORE™ TP core, described in https://www.xilinx.com/products/intellectual-property/fft.html #overviews, retrieved Mar. 9, 2024 and included in Appendix C of U.S. provisional application 63/640,169. In some embodiments, the FFT subsystem output signal comprises in-phase (I) and quadrature (Q) components of multiple frequency bins of a signal. In some embodiments, as will be explained below, output signals produced by FFT subsystem 303 are transmitted over overall interconnections 105 to control subsystem 103 for use by control subsystem 103, as will be explained further below.

Using FPGA-based FFT enables resynthesis with thousands of oscillators, for example, 1,024, 2,048, 4,096 or 8,192 oscillators, rather than hundreds as seen with the prior art software-based approaches. Using higher capacity FPGA enables scaling to more oscillators. This scalability is limited for software-based approaches such as in the Klingbeil reference.

Waveform read control subsystem 305 plays the role of implementing read control logic within waveform subsystem 101. The waveform read control subsystem 305 is triggered by, for example, management subsystem 209 within control subsystem 103 to initiate reads responsive to on-trigger and off-trigger signals received from, for example, controller 123. This will be discussed in further detail below. Once the trigger has been received, waveform read control subsystem 305 issues a plurality of read requests for the descriptor tables stored in the control subsystem 103, as will be explained below. The waveform read control subsystem 305 is provisioned by the management subsystem 209 within control subsystem 103 with base address pointers to the descriptor tables, so the waveform read control subsystem 305 knows where to issue memory read accesses to. In particular, the waveform read control subsystem 305 issues multiple reads for the duration of a note or a sound, with incrementing address indexes into the selected descriptor table, in an effort to keep a continuous stream of descriptor envelope data sent to the oscillator generation subsystem 309. Then, data read from the descriptor tables is received by the waveform read control subsystem 305 via, for example overall interconnections 105. This received data is then processed by waveform read control subsystem 305. Examples of processing operations comprise interpolation and modification of read data. These operations are described below. The processed data is then forwarded by the waveform read control subsystem 305 to the oscillator generation subsystem 309.

In the case of resynthesis, the waveform read control subsystem 305 is triggered by, for example, management subsystem 209 within control subsystem 103 to initiate reads responsive to, for example, commands sent by controller 123 rather than on- and off-triggers. Reading commences when resynthesis mode is entered, and ends when resynthesis mode is exited. In some embodiments, this is performed using a circular buffer approach, that is: During the time between entry into resynthesis mode and exit from resynthesis mode, the waveform read control subsystem 305 issues reads with incrementing address indexes into the selected descriptor table. As one of ordinary skill in the art would know, in line with a circular buffer approach: Once the reading process reaches a final address for the descriptor tables, it jumps back to the base address, and begins reading again.

In some embodiments, the waveform read control subsystem 305 controls the rate at which data is read from the descriptor tables. In some embodiments, this is achieved via controlling the read address increments. This is done to, for example, step through the envelope stages faster. As previously mentioned, there is a velocity status field in the MIDI command.

Then, an example of controlling rate of data read via the read address increments is as follows: The waveform read control subsystem 305 uses the velocity information in conjunction with a velocity sensitivity control to set its read address increment to the descriptor tables. Then, when the velocity sensitivity control is increased, the read address increment is also increased. This means that the descriptors are read faster, and stages are completed quicker, which affects the sound produced.

An example is as follows: read address increment is given as [1+(velocity sensitivity)×velocity]. In some embodiments, a set of read addresses after incrementing is rounded down to the nearest integer value. For example, if read address increment is 1.8 and the counter begins at zero (0), then an example set of read addresses is:
{1.8, 3.6, 5.4, 7.2, 9.0, 10.8}

The waveform read control subsystem 305 then rounds this set down to the nearest integer values, so that the actual issued addresses are:
{1, 3, 5, 7, 9, 10}

One of skill in the art would then appreciate that according to the example above, when velocity sensitivity is increased so that the read address increment is greater than 1.8, the corresponding set of read addresses would have larger values, meaning that the waveform read control subsystem 305 steps through the descriptor table faster.

Oscillator generation subsystem 309 receives the data forwarded by waveform read control subsystem 305, and uses this forwarded data to generate sounds using a plurality of additive oscillators. An illustrative embodiment of oscillator generation subsystem 309 is described below, with reference to FIGS. 2B and 2C.

FIG. 2B shows an example embodiment of an additive oscillator 2B-01. Additive oscillator 2B-01 is created based on a sum of plurality of sine wave partial oscillators 2B-05-01 to 2B-05-N. Each of the plurality of partial oscillators has associated parameters. Examples are shown in FIG. 2B. In FIG. 2B, partial oscillators 2B-05-01, 2B-05-02 to 2B-05-N are associated with partial parameters 2B-19-01, 2B-19-02 to 2B-19-N respectively.

Examples of partial parameters are:
Frequency,
Amplitude,
AM frequency,
AM gain,
FM frequency, and
FM gain.
Further explanations of these example partial parameters are given below.

Each of the partial oscillators 2B-05-01 to 2B-05-N has a corresponding partial frequency 2B-07-01 to 2B-07-N as shown in FIG. 2B. For example, partial oscillator 2B-05-01 has partial frequency 2B-07-01.

Additive oscillator 2B-01 has associated fundamental frequency 2B-03. In some embodiments, the additive oscillator is placed into a normal control mode, where the fundamental frequency 2B-03 is the lowest partial frequency within the group of partial frequencies 2B-07-01 to 2B-07-N. In some embodiments, the fundamental frequency 2B-03 is set based on user input from an external controlling device, such as controller 123 or another device running Digital Audio Workstation (DAW) software. For example, the MIDI Note On protocol includes a status byte which indicates which note is to be played. This note information can be used to index a table that stores frequency information corresponding to that note. This frequency information is programmed into an additive oscillator to set its fundamental frequency, allowing for a tone to be generated at the desired pitch, as will be explained below.

In the normal control mode, each of the group of partial frequencies 2B-07-01 other than the fundamental frequency 2B-03 is based on an integer or non-integer multiple of the fundamental frequency. This is a distinction over traditional subtractive synthesizers as explained previously. Typically, subtractive synthesizers use integer harmonically related signals such as a square wave or sawtooth wave. As explained previously, allowing for partial frequencies to be based on non-integer multiples of the fundamental may result in timbres that cannot be generated using subtractive synthesizers. As will be explained below, the spacing between each of the partial frequencies is adjustable.

In some embodiments, the additive oscillator is placed into a Gaussian control mode, where the fundamental frequency 2B-03 becomes the centermost frequency within the group of partial frequencies 2B-07-01 to 2B-07-N. Then, partial frequency location relative to the fundamental frequency alternates based on whether the partial is odd or even numbered. For example, in one embodiment, even-numbered partial frequencies, for example, 2B-07-02 are higher than the fundamental, and odd-numbered partial frequencies such as 2B-07-01 are lower than the fundamental. The Gaussian control mode can be useful for generating, for example, percussive and formant sounds.

Each of the partial oscillators 2B-05-01 to 2B-05-N also has a corresponding partial amplitude 2B-09-01 to 2B-09-N as shown in FIG. 2B. In some embodiments, one or more of the partial amplitudes 2B-09-01 to 2B-09-N are set based on user input, as will be explained below. Similarly, one or more of the partial frequencies 2B-07-01 to 2B-07-N are set based on user input, as will also be explained below.

As explained above, each of the sine wave partial oscillators in an additive oscillator has an associated partial frequency, which is an integer or non-integer multiple of the fundamental. In some embodiments, there are deviations from this partial frequency. These frequency deviations give rise to a larger state space of potential timbres when compared to the square, sawtooth and other waveforms of subtractive synthesis.

The amplitude, frequency spacing and frequency deviation of each partial within the additive oscillator can be controlled coarsely or macro controlled as a group; or individually or micro controlled using the descriptor tables.

An example of coarse or macro control is setting frequency spacing between the partials using a frequency spacing parameter A within the additive oscillator. For example,
F is the fundamental frequency,
F×2×Δ is the frequency of the 2^{nd} partial oscillator,
F×3×Δ is the frequency of the 3^{rd} partial oscillator, and so on.
   Then, Δ can be applied to all partials based on user input. Since it is applied to all partials, it is a coarse or macro control. A is set using a user input applied via, for example, a potentiometer. Potentiometers and other devices to enable user inputs will be discussed below.

Another example of coarse control is setting rolloff parameters for the rolloff controls. The rolloff controls work on the partial oscillators similar to a low pass or a high pass filter, in that it modifies the amplitude of the frequency content of the signal. Then, there is a transfer function associated with the rolloff control, and the shape of the rolloff transfer function is set based on the rolloff parameters. The rolloff transfer function is then applied to all partial amplitudes, and the rolloff parameters which determine the transfer function are set using a user input applied via, for example, one or more potentiometers. Potentiometers and other devices to enable user inputs will be discussed below.

Individual or micro control for each partial over a range of parameters can also be applied using the descriptors. Using the descriptors in this way offers further flexibility for additive synthesizers when compared to subtractive synthesizers. As explained above, subtractive synthesizers use harmonically rich but integer harmonically-related signals such as a square wave or sawtooth wave. Additive synthesizers offer the additional capability to place a partial frequency at a non-integer multiple of the fundamental frequency which enhances flexibility. Additionally, as will be explained below, individual partial frequencies can be disabled and enabled, selectively. Descriptors allow for micro control of each partial frequency, thereby further enhancing flexibility. A detailed explanation of how descriptors can be generated and used to provide individual or micro control is provided below.

Each of the partial oscillators 2B-05-01 to 2B-05-N has an AM sine wave oscillator associated with it, and is used to provide AM for its partial oscillator. The partial AM frequency is the frequency of the AM sine wave oscillator. Then, each of the partial oscillators 2B-05-01 to 2B-05-N is associated with one of the corresponding partial AM frequencies 2B-11-01 to 2B-11-N, as shown in FIG. 2B. In some embodiments, one or more of the partial AM frequencies 2B-11-01 to 2B-11-N are set based on user input, as will be explained below.

The partial AM gain is the gain of the AM sine wave oscillator. Then, each of the partial oscillators 2B-05-01 to 2B-05-N is associated with one of the corresponding partial AM gains 2B-13-01 to 2B-13-N, as shown in FIG. 2B. In some embodiments, one or more of the partial AM gains 2B-13-01 to 2B-13-N are set based on user input, as will be explained below.

Each of the partial oscillators 2B-05-01 to 2B-05-N has a FM sine wave oscillator, which is used to provide FM for its partial oscillator. The partial FM frequency is the frequency of the FM sine wave oscillator. Then, each of the partial oscillators 2B-05-01 to 2B-05-N is associated with one of the corresponding partial FM frequencies 2B-15-01 to 2B-15-N, as shown in FIG. 2B. In some embodiments, one or more of the partial FM frequencies 2B-15-01 to 2B-15-N are set based on user input, as will be explained below.

The partial FM gain is the gain of the FM sine wave oscillator. Then, each of the partial oscillators 2B-05-01 to 2B-05-N is associated with one of the corresponding partial FM gains 2B-17-01 to 2B-17-N, as shown in FIG. 2B. In some embodiments, one or more of the partial FM gains 2B-17-01 to 2B-17-N are set based on user input, as will be explained below.

Each additive oscillator is generated by an additive oscillator generation unit. An example embodiment of an additive oscillator generation unit 2C-01 is shown in FIG. 2C. As explained above and with reference to FIG. 2B, each additive oscillator is created based on a sum of plurality of partial oscillators. For example, if there are 256 additive oscillators, each based on a sum of 32 partial oscillators, then the additive oscillator generation unit generates 8,192 unique sine waves. Creating such a large number of sine waves is computationally complex, and was difficult to achieve using the architectures described in prior art systems. Using FPGA-based architectures enables this computationally complex undertaking to occur.

In some embodiments, each additive oscillator has a plurality of Low Frequency Oscillators (LFOs) associated with it. Then, the additive oscillator generation unit 2C-01 comprises LFO module 2C-09. LFO module 2C-09 enables adjustment of the above-mentioned plurality of LFOs which are used to modulate characteristics of the additive oscillator partials, such as the partial amplitudes 2B-09-01 to 2B-09-N, and the partial frequencies 2B-07-01 to 2B-07-N. In some embodiments, LFO module 2C-09 is controlled based on user inputs provided through input devices such as a touchscreen or a potentiometer, as will be explained below.

As explained above, the LFOs are used to modulate characteristics of the additive oscillator partials. For example, in the arrangement described in the Draft User Manual, each additive oscillator has eight (8) associated LFOs:
AM,
FM,
amplitude parameter APA,
amplitude parameter APB,
amplitude parameter APC,
frequency parameter FPA,
frequency parameter FPB, and
frequency parameter FPC.
   In some embodiments, each of the LFOs are comprised of one to four partial additive oscillators.

The LFOs associated with AM and FM provide the same amount of amplitude and frequency modulation to all partial oscillators.

The LFOs associated with the amplitude parameters APA, APB and APC are used to apply additional amplitude modifications to the partial oscillators in the additive oscillator. In some embodiments, these LFOs provide amplitude modifications that mimic resonance behaviors found in subtractive synthesis low pass filters. These amplitude modifications are performed for each partial by indexing an amplitude curve lookup table that stores an amplitude curve parameter, and then applying an amplitude modification based on the retrieved amplitude curve parameter to each partial in turn. A process to do so is outlined below.

Amplitude parameters APA, APB and APC each have the following associated parameters:
A fundamental frequency setting for the LFO,
A gain setting, and
A bias setting.

The APA value sets the starting address of the first partial index into the table. In LFO module 2C-09, the initial APA value generated at a given time is determined by:
The value based on a fundamental frequency setting for the APA LFO;
The APA LFO gain setting; and
The APA bias setting.

The APB setting determines the width of the amplitude resonance by setting the address increment into the table. The initial APB value generated at a given time is set by:
The value based on a fundamental frequency setting for the APB LFO at that given time;
The APB LFO gain setting; and
The APB bias setting.

The index into the amplitude curve lookup table for the nth partial is then given by: indexamp(n)

$$= \{ \begin{matrix}APA + ( n \times APB ) , & when APA + ( n \times APB ) \leq A\_LUT \_size , \\ A\_LUT \_size - ( ( APA + ( n \times APB ) \% A\_LUT \_size ) , & when APA + ( n \times APB ) > A\_LUT \_size\end{matrix}$$

where indexamp(n) is the index into the amplitude curve lookup table for the nth partial,
APA is the APA setting,
APB is the APB setting,
n is the partial number,
A_LUT_size is the size of the amplitude curve lookup table, and
% represents the modulo or remainder operation.

For example, when:
A_LUT_size=1,
APA=0.4, and
APB=0.1;
   The indexamp(n) for partials 1 to 7 are given by the following:

| Partial (n) | indexamp(n) |
|---|---|
| 1 | 0.5 |
| 2 | 0.6 |
| 3 | 0.7 |
| 4 | 0.8 |
| 5 | 0.9 |
| 6 | 1.0 |
| 7 | 0.9 |

Referring to the above table, the index for partial 7 is given by 0.9, since 1-(1.1%1)=0.9.

One of ordinary skill in the art would appreciate that since the APA and APB values are determined by oscillators, these values could fluctuate over time.

Furthermore, one of ordinary skill in the art would understand that when APB is small relative to APA, the index into the amplitude curve lookup table does not vary much from APA for the partials.

Then, the per partial value is read using the amplitude curve lookup table. The APC value is used to control an attenuation applied to the value retrieved from the look up table. This allows an amplitude modification such as the previously described resonance behavior to be attenuated or be full scale. The APC value generated at a given time is set by:
The value of the APC LFO at that given time;
The APC LFO gain setting; and
The APC bias setting.

Similarly, the frequency parameters FPA, FPB and FPC are used to apply additional frequency modifications to the partials in the additive oscillator.

Similar to amplitude, this is performed for each partial by indexing a frequency curve lookup table that stores a frequency curve parameter, and then applying that value as a frequency compression or expansion to each partial in turn. A process to do so is outlined below.

Similar to amplitude parameters APA, APB and APC; frequency parameters FPA, FPB and FPC each have the following associated parameters:
A fundamental frequency setting for the LFO,
A gain setting, and
A bias setting.

The FPA value sets the starting address of the first partial index into the frequency curve lookup table. In LFO module 2C-09, the initial FPA value generated at a given time is set by:
The value based on a fundamental frequency setting for the FPA LFO;
The FPA LFO gain setting; and
The FPA bias setting.

The FPB setting determines the width of the frequency resonance by setting the address increment into the frequency curve lookup table. The initial FPB value generated at a given time is set by:
The value based on a fundamental frequency setting for the FPB LFO at that given time;
The FPB LFO gain setting; and
The FPB bias setting.

The index into the frequency curve lookup table for the nth partial is then given by: indexfreq(n)

$$= \{ \begin{matrix}FPA + ( n \times FPB ) , & when FPA + ( n \times FPB ) \leq F\_LUT \_size , \\ F\_LUT \_size - ( ( FPA + ( n \times FPB ) \% F\_LUT \_size ) , & when FPA + ( n \times FPB ) > F\_LUT \_size\end{matrix}$$

where indexfreq(n) is the index into the frequency curve lookup table for the nth partial,
FPA is the FPA setting,
FPB is the FPB setting,
n is the partial number,
F_LUT_size is the size of the frequency curve lookup table, and
% represents the modulo or remainder operation.

For example, when:
F_LUT_size=1,
FPA=0.4, and
FPB=0.1;
   The indexfreq(n) for partials 1 to 7 are given by the following:

| Partial | indexfreq(n) |
|---|---|
| 1 | 0.5 |
| 2 | 0.6 |
| 3 | 0.7 |
| 4 | 0.8 |
| 5 | 0.9 |
| 6 | 1.0 |
| 7 | 0.9 |

Referring to the above table, the index for partial 7 is given by 0.9, since 1-(1.1%1)=0.9.

One of ordinary skill in the art would appreciate that since the FPA and FPB values are determined by oscillators, these values could fluctuate over time.

Furthermore, one of ordinary skill in the art would understand that when FPB is small relative to FPA, the index into the amplitude curve lookup table does not vary much from APA for the partials.

Then, the per partial value is read using the frequency curve lookup table. The FPC value is used to control an attenuation applied to the value retrieved from the look up table. This allows a frequency modification to be attenuated or be full scale. The FPC value generated at a given time is set by:
The sine value of the FPC LFO at that given time;
The FPC LFO gain setting; and
The FPC bias setting.

Further description of embodiments of the LFO module 2C-09, operations performed within the LFO module and user inputs to control the LFO module is provided in section 5.4.1 and pages 20-22 of the Draft User Manual.

The additive oscillator generation unit 2C-01 comprises LFO envelope module 2C-11. LFO envelope module 2C-11 enables the user to design envelopes to control the output applied from each of the plurality of LFOs in module 2C-09 to the additive oscillator over time. Then, the user controls LFO envelope module 2C-11 based on user inputs provided through input devices such as a touchscreen or a potentiometer, as will be explained below.

For example, with specific reference to the arrangement described in the Draft User Manual, the LFO envelope module 2C-11 controls the gain of each of the 8 LFOs before being sent to:
the additive oscillator group AM and FM modulations;
the APA, APB and APC control algorithms; and
the FPA, FPB and FPC control algorithms.

The gain envelope for each LFO can be shaped by the user using the touchscreen, and describes the gain in time of each LFO following on-trigger and off-trigger events such as MIDI Note On and MIDI Note Off. In this way, the gain of each LFO can be controlled for the duration of the note, allowing for the timbre of a note to evolve over time following the trigger events.

Further description of embodiments of the LFO envelope module 2C-11, operations performed within the LFO envelope module 2C-11, and user inputs to control the LFO envelope module 2C-11, are provided in, for example, section 5.4.1 and pages 22-23 of the Draft User Manual.

The additive oscillator generation unit 2C-01 comprises frequency path 2C-05 and amplitude path 2C-07 that run in parallel.

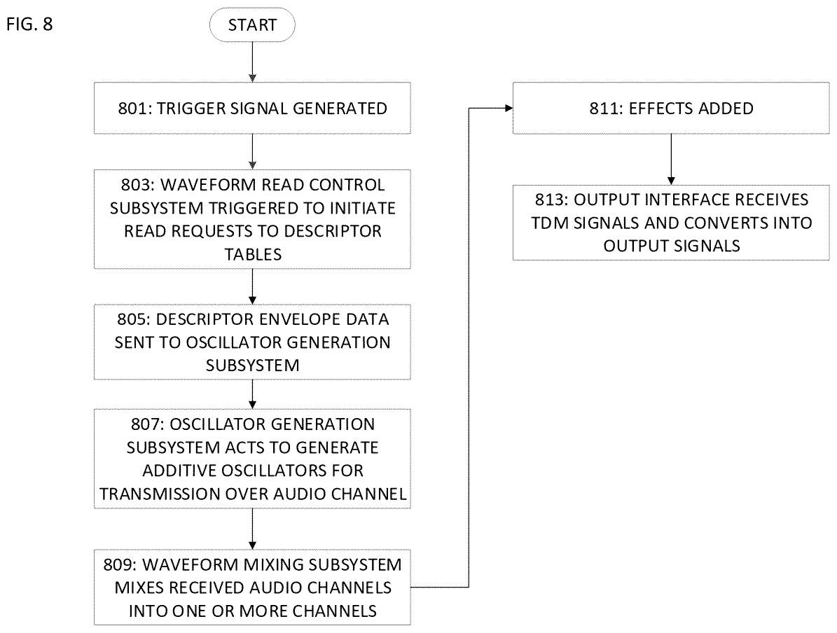

The frequency path 2C-05 is responsible for generating each of the partial frequencies 2B-07-01 to 2B-07-N associated with partial oscillators 2B-05-01 to 2B-05-N. Frequency path 2C-05 outputs a full-scale sine wave at the correct frequency for each sample in a TDM format. This output is controlled based on user inputs provided through input devices such as a touchscreen or a potentiometer, as will be explained below. An example embodiment of the frequency path 2C-05 is provided in Section 5.4.2 and FIG. 8 of the Draft User Manual, specifically in pages 23-25. In some embodiments, frequency path 2C-05 is implemented using a plurality of components.

The frequency path 2C-05 performs this task for each partial by maintaining a table of phase indexes into a sine wave Look Up Table (LUT), then looking up the sine value for the selected phase. On a per sample basis, the frequency module increments each partial's current phase by a phase increment (PI), and stores the incremented phase for the next sample.

The APA, APB and APC values which are output from the LFO envelope module 2C-11, are processed by the APA, APB and APC control algorithms prior to being used in the amplitude path 2C-07. Similarly, the FPA, FPB and FPC values which are output from the LFO envelope module 2C-11, are processed by the FPA, FPB and FPC control algorithms prior to being used in the frequency path 2C-05.

The PI for each partial is calculated based on:
the fundamental frequency set by the MIDI Note On command,
The processing of the outputs from the LFO envelope module 2C-11 processing of the FM value, and the FPA, FPB and FPC values output from the respective FPA, FPB and FPC control algorithms respectively;
Coarse controls related to frequency, for example, the previously described frequency spacing parameter A;
Micro controls such as the descriptor outputs associated with the FM gain, FM frequency and frequency deviation partial parameters for that partial, as will be explained further below; and
Inputs from detuning controls.

Further detail is provided in Section 5.4.2 and FIG. 8 on pages 23-25 of the Draft User Manual. The full-scale sine waves are output from the frequency module in a Time Division Multiplexed (TDM) format.

Further description of the frequency path module 2C-05, operations performed within the frequency path module 2C-05, and user inputs to control the frequency path module 2C-05, are provided in section 5.4.2, FIG. 8, and pages 23-25 of the Draft User Manual.

One of ordinary skill in the art would appreciate that the frequency of each partial amplitude is compressed, expanded or remains the same based on the outputs of the above processes.

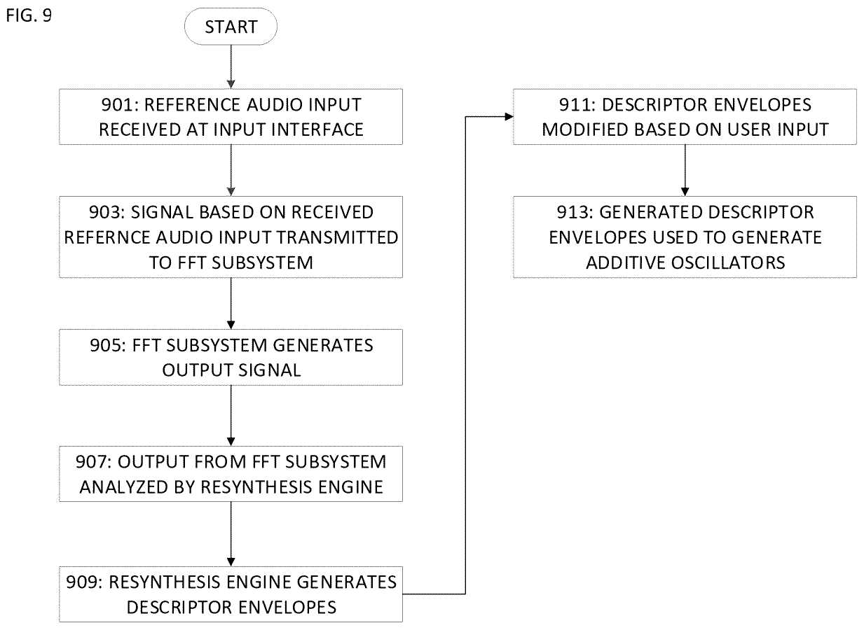

The amplitude path 2C-07 is responsible for generating each of the partial amplitudes 2B-09-01 to 2B-09-N associated with partial oscillators 2B-05-01 to 2B-05-N. An example embodiment of the amplitude path 2C-07 is provided in Section 5.4.3 and FIG. 9 of the Draft User Manual, specifically in pages 25-27. In some embodiments, amplitude path 2C-07 is implemented using a plurality of components.

In some embodiments, based on user inputs provided through input devices 202 such as a touchscreen or a potentiometer, one or more of the partials are disabled. Then, each partial can be selectively muted or unmuted by the user, which gives rise to a further range of timbres not available through subtractive synthesis, such as bell sounds and others.

The amplitude path of the additive oscillator is used to compute that amplitude of each partial prior to summation. The amplitude of each partial is calculated based on:
The processing of the outputs from the LFO envelope module 2C-11 processing of the FM value;
The APA, APB and APC values output from the corresponding APA, APB and APC control algorithms;
Coarse controls related to amplitude, for example, the previously described rolloff parameters;
Micro controls such as the descriptor outputs associated with the AM gain, AM frequency and amplitude partial parameters for that partial, as will be explained below; and
Inputs to either enable or disable the particular partial, as described above.
   Further detail is provided in Section 5.4.3 and FIG. 9 on pages 25-27 of the Draft User Manual. The amplitude of each partial is output from the amplitude module in a TDM format similar to the output of the frequency module.

One of ordinary skill in the art would appreciate that the amplitude of each partial is attenuated, amplified or remains the same based on the outcomes of the above processes.

The outputs of the frequency path 2C-05 and the amplitude path 2C-07 are combined in the additive oscillator output block 2C-13. Firstly, for each partial oscillator, the outputs from the frequency path 2C-05 and the amplitude path 2C-07 are multiplied together in multiplication block 2C-15.

Then, for each additive oscillator, the plurality of partial oscillators are summed together in summation block 2C-17. This is performed for all of the additive oscillators. Each of the additive oscillators is then output into a corresponding audio channel such as audio channel 2C-19. Audio channel 2C-19 has an associated bit rate determined by:
the number of bits per sample or bit depth, and
audio sample rate.
   Further description of the additive oscillator output subsystem 2C-13 is provided in sub-section 5.4.4 of the Draft User Manual, which can be found in page 27.

As explained before, the low latency behaviour of the FPGA-based architecture enables all of the above processing to be performed in real-time on a per sample basis. This stands in contrast to software implementations which rely on buffering several samples before processing these, leading to longer latency.

In some embodiments, the audio channels are routed to the waveform mixing subsystem 315 via waveform subsystem interconnections 313. These audio channels originate from, for example:
Input interface 301,
Waveform effects subsystem 311, and
Additive oscillator output subsystem 2C-13.

The waveform mixing subsystem 315 mixes received signals received from multiple audio channels into a single output for transmission over a channel. In some embodiments, gains for each input audio channel are set automatically depending on the number of channels mixed, so that nonlinear distortions such as saturation and overflow are avoided. In some embodiments, users supply inputs using input devices such as potentiometers and other devices to control the mixing operations. For example, a user can increase the volume of the mixed channels using a mixer gain potentiometer control.

In some embodiments, the waveform mixing subsystem supports multiple mixing configurations, which can be controlled based on user input. For example, all voices in a polyphonic instrument setup could be mixed together, and this mixed channel can be routed to the waveform effects subsystem 313. In yet other embodiments, the waveform mixing subsystem 315 is configured to mix certain groupings of channels together for output to the digital-to-analog converters (DACs) in output interface 307 which will be discussed below. For example, waveform mixing subsystem 315 mixes:
a first group of channels for a DAC corresponding to a line out “left” signal output;
a second group of channels for a DAC corresponding to a line out “right” signal output;
a third group of channels for a DAC corresponding to an analog out signal output; and
a fourth group of channels for a DAC corresponding to a line out aux signal output. Then each of these signal outputs has its own mix of channels.

In some embodiments, waveform mixing subsystem 315 mixes all channels for one or more signal outputs. For example, waveform mixing subsystem 315 mixes all channels for a headphones signal output. An example embodiment of the waveform mixing subsystem 315 is described in section 5.6 of the Draft User Manual, which can be found in page 28.

In some embodiments, one or more of the audio channels are routed via waveform subsystem interconnections 313 to waveform effects subsystem 313 for addition of effects. This routing takes audio channels output from the below, including but not limited to, for example:
Waveform mixing subsystem 315,
Additive oscillator output subsystem 2C-13, and
Input interface 301.

An example embodiment of the waveform effects subsystem is described in section 5.5 of the Draft User Manual, which can be found in pages 27-28. Examples of effects comprise reverb effects, compression effects, sample and hold effects, quantization effects and chorus effects.

Output interface 307 comprises, one or more audio transmission devices and implements one or more technologies known to those of skill in the art, to perform the role of transmitting signal outputs 109. Examples of such audio transmission devices comprise speakers, BLUETOOTH® transmitters and audio jacks. Then, output interface 307 receives the time division multiplexed signals from waveform subsystem interconnections 313, produces, and transmits output signals 109. Examples of signal outputs 109 are Headphones, Line Out, Line Out Aux, and Analog Out signal outputs. Signal outputs 109 comprise, for example:
Signals for transmission over a wired connection such as an audio cable;
Signals for transmission over a wireless connection such as BLUETOOTH® or Wi-Fi;
Sound waves for over-the-air transmission.
   In some embodiments, output interface 307 performs one or more processing steps to enable output signals 109 to be transmitted as required amongst others.

In some embodiments, output interface 307 comprises a DAC module which has one or more DACs, as mentioned above. Each of the one or more DACs corresponds to one of the signal outputs 109. For each of signal outputs 109, the DAC module selects the corresponding group of audio channels from the waveform subsystem interconnections 313 and directs the selected group of audio channels to the DAC corresponding to that signal output. The DAC converts the signals from digital format into analog format, and the converted analog signal drives analog output circuits to the output connector corresponding to that signal output. Further details of an example embodiment of the DAC modules are provided in Section 5.7 of the Draft User Manual, which is located on page 28.

In some embodiments, at least one of the signal outputs is a mono output, that is, only one channel. In other embodiments, at least one of the signal outputs comprises different channels, such as:
a left and a right channel in the case of a stereo output; or
four (4) different channels in the case of a quadraphonic or “quad” output.
   Then, in some of these embodiments, the processing comprises performing operations to generate channel outputs, wherein each channel output corresponds to one of the different channels.

For example, in the case of stereo processing, each of the left and right channels which are output from the waveform effects subsystem 311 are generated based on:
Sending similar versions of one or more additive oscillators to each of the left and right channel, wherein the versions have phase differences. This results in a fuller sound.
Sending different versions of one or more oscillators, each configured differently, to each of the left and right channel. An example of this is where the versions have complimentary partials. For example:
   version 1 of the additive oscillator has odd-numbered partials such as partials 1, 3, 5 and 7 enabled, and version 1 is sent to the left channel, and
   version 2 of the additive oscillator has even-numbered partials enabled, and version 2 is sent to the right channel.
One of ordinary skill in the art would appreciate that different processing operations could be applied to generate the different versions between the left and right groups. As a result of these operations, some of the parameters may stay the same, while others may differ.

Similar techniques can be used in the case of a quad output. For example:
the same groups of oscillators are sent to the 4 channels, but with different phases for each channel, or
different portions of a signal are routed to different channels. For example, different partials are sent to different channels.

As explained above, waveform subsystem processor 317 plays the role of coordinating the operations of waveform subsystem 101. In some embodiments, one or more of the components of waveform subsystem 101 have their own dedicated processor. For example, in some embodiments, waveform effects subsystem 311 has its own dedicated processor.

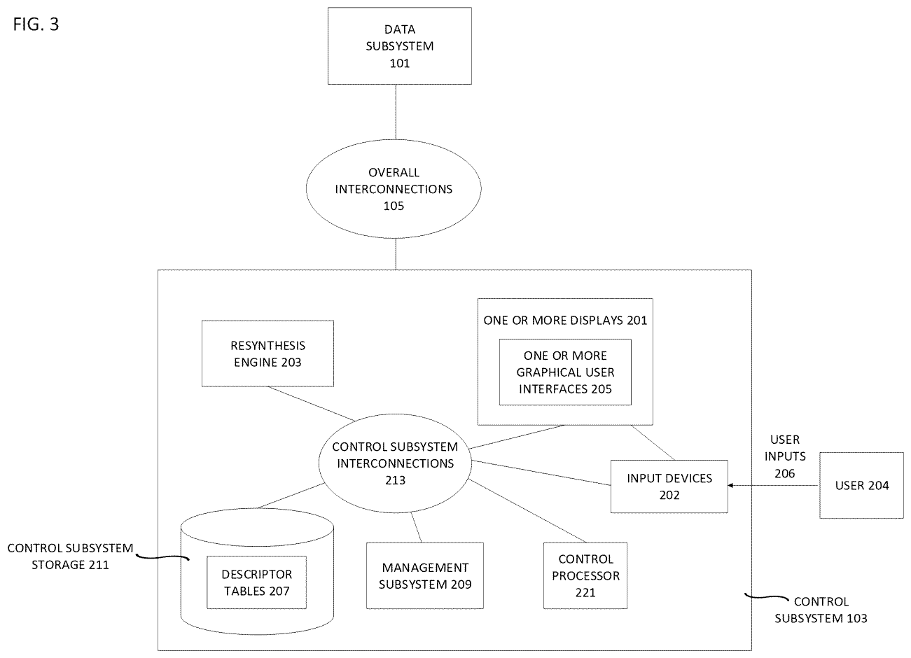

An example embodiment of control subsystem 103 is shown in FIG. 3. Control subsystem 103 comprises resynthesis engine 203, display 201 which displays graphical user interface 205, input devices 202, management subsystem 209, control subsystem storage 211 which stores descriptor tables 207, and control subsystem interconnections 213.

Control subsystem storage 211 stores data and programs necessary for the operation of control subsystem 103. Control subsystem storage 211 is implemented using, for example, non-volatile memory such as SD cards, or volatile memory such as dynamic RAM (DRAM), or a combination of both. In some embodiments, control subsystem storage 211 is implemented using embedded FPGA static RAM (SRAM).

As shown in FIG. 3, control subsystem storage 211 stores descriptor tables 207. Descriptors are envelopes comprising a plurality of stages. As explained previously, descriptors allow for individual or micro control of partial parameters and therefore the partial oscillators which make up an additive oscillator. Descriptor tables 207 are buffers allocated in control subsystem storage 211 by management subsystem 209 that store descriptors.

The usage of descriptors to modify the behaviour of partial oscillators is described in detail below. Descriptor tables 207 are populated from:
one or more graphical user interfaces 205, responsive to user inputs 206 provided by user 204 via input devices 202, and
the resynthesis engine 203 which analyzes the frequency content of the FFT subsystem output signal and generates descriptor envelopes to regenerate that signal using sine waves.
   Processes to populate descriptor tables will be described below. Descriptors are also described in more detail in section 6.4 and pages 39-49 of the Draft User Manual.

In some embodiments, there are different descriptor tables corresponding to different trigger events. For example, in some embodiments there are on-trigger descriptor tables and off-trigger descriptor tables.

Resynthesis engine 203 analyzes the frequency content of the FFT subsystem output signal produced by the FFT subsystem 303, and generates descriptor envelopes to enable oscillator generation subsystem 309 of waveform subsystem 101 to generate appropriate additive oscillators. As explained previously, in some embodiments, resynthesis engine 203 obtains an FFT subsystem output signal that describes the I and Q components of multiple frequency bins of a reference audio input. Resynthesis engine 203 then calculates the amplitude and phase of each frequency bin from the complex I and Q components from the FFT subsystem output signal.

Using the per bin amplitude and phase components, resynthesis engine 203 generates descriptor envelopes to match the phase and amplitude of the analyzed signal and stores those in the descriptor tables 207 in control subsystem storage 211 in real-time by populating only a portion of the descriptor associated with the latest FFT result. Further details of an embodiment of a resynthesis engine are provided in Section 7 of the Draft User Manual, on pages 53-54. In some embodiments, this is performed using a circular buffer approach as explained previously. As explained above, the population process commences when resynthesis mode is entered, and ends when resynthesis mode is exited.

Input devices 202 allow users such as user 204 to provide user inputs 206 and thereby control the operation of system 100. Examples of input devices 202 comprise, for example, potentiometers, touchscreens, keyboards, keypads, mouse, etc. Some of these example embodiments of input devices 202 are described in section 6.1 from pages 30-35 of the Draft User Manual. For example, potentiometer embodiments and touchscreens are described in section 6.1.1 and 6.1.2 of the Draft User Manual, on pages 30-35. Examples of the use of input devices such as potentiometers and touchscreens to accept user inputs and perform required functions and operations have been provided previously, and also in the Draft User Manual. Further examples will be provided below.

One or more graphical user interfaces (GUIs) 205 are displayed on one or more displays 201 and are activated by one or more of user inputs 206, which are provided by user 204 using input devices 202.

Control processor 221 performs the role of coordinating the operation of control subsystem 103. In some embodiments, these functions are performed by waveform subsystem processor 317. An example of such an embodiment is where control subsystem 103 is stored on waveform subsystem processor 317.

Management subsystem 209, which was previously mentioned above, plays the role of system initialization, memory allocation and provisioning of hardware resources. In some embodiments, management subsystem 209 allocates memory buffers in control subsystem storage 211. In some embodiments, management subsystem 209 communicates pointers to the start of these memory regions to the waveform read control subsystem 305 in the waveform subsystem 101, so as to enable the waveform read control subsystem 305 to issue read requests. Management subsystem 209 also informs the resynthesis engine, one or more GUIs 205 and the control processor 221 of the addresses associated with descriptor tables 207 in control subsystem storage 211 so that the descriptor tables 207 are appropriately populated when required.

One or more of management subsystem 209 and control processor 221 are interrupted when commands and triggers such as MIDI commands are received from controller 123. Then one or more of management subsystem 209 and control processor 221 perform functions such as:
Reading the received command;
Decoding the command. When the command is a MIDI command, one of more of management subsystem and control processor 221 decodes the received command in accordance with the MIDI protocol;
Parsing the decoded information in the received command, which includes, for example, reading status fields and other information in the command;
Based on the parsed information, creating and sending triggers to the waveform read control subsystem 305 to initiate read requests.
Based on the parsed information for parameters such as aftertouch and other control variables, update control variables within the waveform read control subsystem 305 to modify descriptor read data and other control variables as status information is received over MIDI.

In some embodiments, one or more of management subsystem 209 and control processor 221 receive the read requests for descriptors issued by waveform read control subsystem 305. Based on these received read requests, one or more of management subsystem 209 and control processor 221 then retrieve the descriptors from control subsystem storage 211.

As explained above, the behaviour of the partial parameters of each partial oscillator associated with an additive oscillator can be modified and controlled by user 204 based on:
The processing of the outputs from the LFO envelope module 2C-11 processing of
   the AM and FM values,
   the APA, APB and APC values output from the respective APA, APB and APC control algorithms respectively;
   the FPA, FPB and FPC values output from the respective FPA, FPB and FPC control algorithms respectively;
Coarse controls such as the frequency spacing parameter A and the rolloff parameters;
Micro controls such as the descriptors associated with:
   the FM gain, FM frequency and frequency deviation partial parameters for each partial, and
   the AM gain, AM frequency and amplitude partial parameters for each partial;
Inputs to enable or disable partials; and
Inputs from detuning controls.

Then, each of these modifications and controls can be performed by the user providing user inputs 206 to input devices 202. Various examples have been previously explained and provided above. Further examples are explained below and in further detail in Section 6.1 of the Draft User Manual.

As also explained above, descriptors stored in descriptor tables 207 can be populated from one or more GUIs 205 responsive to user inputs 206 to input devices 202 provided by user 204. A process to populate descriptor tables 207 using one or more GUIs in conjunction with control processor 221 is described below.

In some embodiments, two different ones of the one or more GUIs are used to perform this process. For example, a first of the one or more GUIs is used to set up one or more stages comprising one or more time values, responsive to user 204 providing user inputs 206 to input devices 202. Each of these one or more time values indicate when a partial parameter should achieve a particular value following a trigger event.

Then, the user sets the particular value of a partial parameter using a second of the one or more GUIs to enter one or more corresponding partial parameter sequences corresponding to the stages. Examples of partial parameters have been given and explained previously. These include but are not limited to:
Amplitude;
Frequency;
AM Frequency;
AM Gain;
FM Frequency; and
FM Gain.

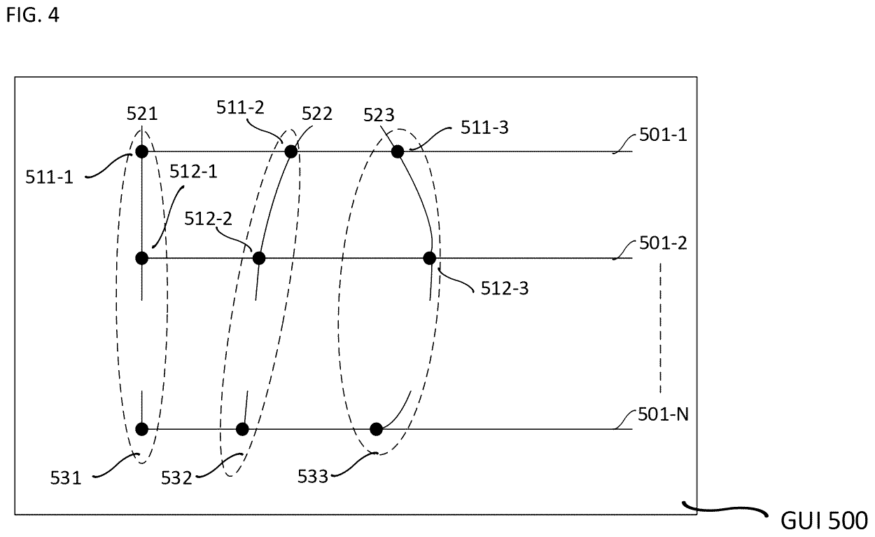

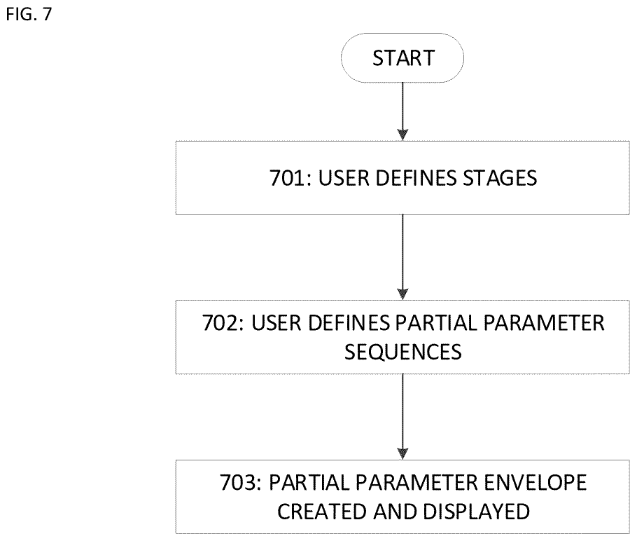

An example is shown below for the amplitude parameter with reference to FIGS. 4-7. The process described below is implemented by control processor 221 in conjunction with other components such as input device 202, GUIs such as GUIs 500 and 600 and displays 201. FIGS. 4-6 illustrate different displays on a graphical user interface, while FIG. 7 illustrates an example embodiment of a process to create and display a partial parameter envelope.

In FIG. 4, GUI 500 displays timelines 501-1 to 501-N, each of which correspond to one or more partial oscillators. For example, timeline 501-1 corresponds to partial oscillator 2B-05-01 from FIG. 2B; timeline 501-2 corresponds to partial oscillator 2B-05-02 from FIG. 2B; and so on.

In step 701 of FIG. 7, a user defines stages using inputs from one of the input devices. In some embodiments, this is facilitated by drawing stage curves. By drawing the stage curve on the time screen, the user is setting a point in time following a trigger such as an on-trigger, for example, a MIDI Note On trigger, or an off-trigger, for example, a MIDI Note Off trigger, that a partial parameter will reach a desired value. In some embodiments, the stage curves are drawn using user input on a touchscreen, such as shown in page 41 of the Draft User Manual. Then, a GUI such as GUI 500 of FIG. 4 is responsive to this user input to draw stage curves 521, 522 and 523. Stages 531, 532 and 533 correspond to stage curves 521, 522 and 523. Each of these stages comprise time values corresponding to where the time curves intersect the timelines. For example:
Stage 531 corresponding to curve 521 comprises:
   time value 511-1, where curve 521 intersects timeline 501-1, and
   time value 512-1, where curve 521 intersects timeline 501-2;
Stage 532 corresponding to curve 522 comprises:
   time value 511-2, where curve 522 intersects timeline 501-1, and
   time value 512-2, where curve 522 intersects timeline 501-2; and
Stage 533 corresponding to curve 523 comprises:
   time value 511-3, where curve 523 intersects timeline 501-1, and
   time value 512-3, where curve 523 intersects timeline 501-2.

In some embodiments, the stages and therefore the stage curves correspond to the stages which follow the start of an on-trigger command. An example is the attack-decay-sustain-release (ADSR) stages which follows the start of a MIDI Note On command. For example, with reference to FIG. 4, stage curve 521 corresponds to the start of a MIDI Note On command, which is the beginning of the attack stage. Stage curve 522 corresponds to the end of the attack stage and the beginning of the decay stage of a MIDI Note On command. Stage curve 523 corresponds to the end of the decay stage, and the beginning of the sustain stage. One of ordinary skill in the art would understand that the user is not limited to an ADSR arrangement.

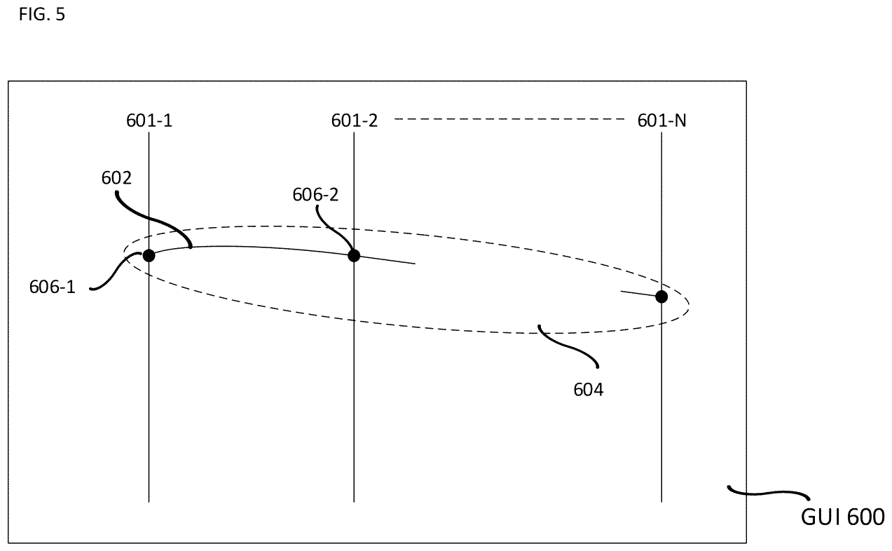

Then in step 702 of FIG. 7, the user defines a partial parameter sequence corresponding to each stage by entering inputs from one of the input devices. This sequence represents the desired values of the partial parameter in each stage. In some embodiments, this is facilitated using partial parameter curves. Then, the partial parameter curves are drawn using user input on a touchscreen, such as shown in p. 42 of the Draft User Manual. An example using a GUI responsive to this user input on a touchscreen is shown in FIG. 5 for the amplitude partial parameter. In FIG. 5, GUI 600 displays vertical lines 601-1 to 601-N, each of which correspond to a partial. For example, vertical line 601-1 corresponds to partial 2B-05-01 from FIG. 2B; vertical line 601-2 corresponds to partial 2B-05-02 from FIG. 2B; and so on.

GUI 600 is responsive to user input on a touchscreen to draw amplitude curve 602 corresponding to stage 532. Then amplitude sequence 604 comprises amplitude values 606-1 to 606-N corresponding to the intersection of amplitude curve 602 with the vertical lines. For example:
amplitude value 606-1 corresponds to the intersection of vertical line 601-1 with amplitude curve 602; and
amplitude value 606-2 corresponds to the intersection of vertical line 601-2 with amplitude curve 602.

Then, based on steps 701 and 702 above, descriptor tables 207 are populated accordingly. As explained previously, management subsystem 209 informs GUIs 500 and 600 of the addresses associated with descriptor tables 207 in control subsystem storage 211 so that the descriptor tables 207 are appropriately populated. As explained previously, in some embodiments there are on-trigger and off-trigger descriptor tables. Then, since the above corresponds to an on-trigger event, in those embodiments the on-trigger descriptor tables are populated.

In step 703, based on the performance of steps 701 and 702, a partial parameter envelope is created and displayed. The creation and display of this partial parameter envelope is performed using, for example, control processor 221 in conjunction with one or more displays 201 of FIG. 3.

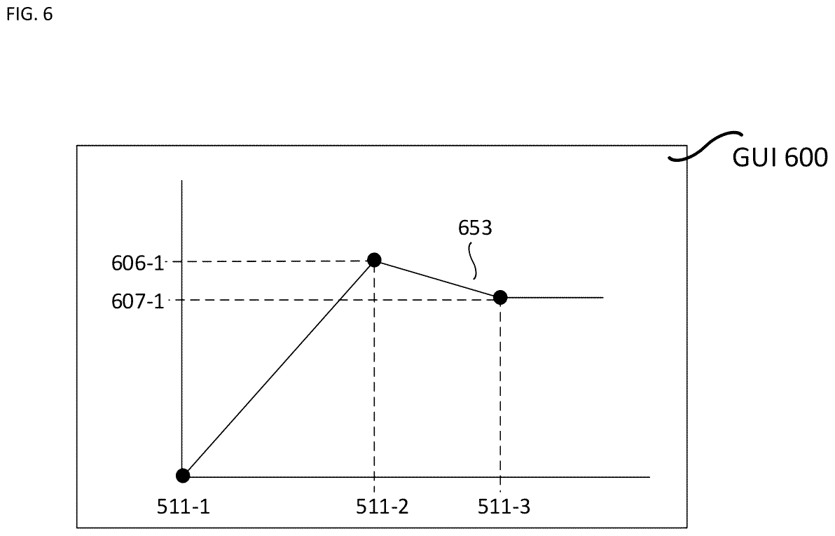

An example display of an amplitude envelope is shown in FIG. 6 for partial oscillator 2B-05-01 of FIG. 2B, and for a MIDI Note On command. As previously explained with reference to FIG. 4, timeline 501-1 corresponds to partial oscillator 2B-05-01. With reference to FIG. 5, vertical line 601-1 also corresponds to partial 2B-05-01. Stage 531 corresponding to stage curve 521 denotes to the start of the MIDI Note On command, that is, the start of the attack phase. Here the amplitude is set to near zero. Since stage curve 521 intersects timeline 501-1 at time 511-1, then at time 511-1 the amplitude is set to near zero.

Stage 532 corresponding to stage curve 522 denotes the end of the attack phase and the start of the decay phase. Time curve 522 intersects timeline 501-1 at time value 511-2. Amplitude curve 602 corresponds to time sequence 532, and intersects vertical line 601-1 at amplitude 606-1. Then, at time value 511-2, the amplitude is set to value 606-1.

A similar determination can be made for the next phase which is the sustain phase. As shown in FIG. 4, time sequence 533 corresponding to time curve 523 intersects timeline 501-1 at time value 511-3. This denotes the end of the decay phase, and the start of the sustain phase. At time value 511-3, the amplitude is set to value 607-1, which corresponds to the intersection of the amplitude curve corresponding to time sequence 533 and vertical line 601-1.

Then, based on the above, amplitude envelope 653 is drawn. In some embodiments, linear segments are used to join the points. In some embodiments, amplitude envelopes corresponding to each of the partials can be drawn on the display. The user can then see how all partials in the additive oscillator evolve over time. In some additional embodiments, both the trigger on and trigger off curves can be displayed on the same screen, with a vertical bar added to show the sustain start point and the trigger off point.

While the above demonstrates an example embodiment where the attack stage begins immediately after the trigger command is received, one of skill in the art would know that there are embodiments where there is an offset time between the receipt of a trigger command and the start of the attack stage.

One of skill in the art would understand that similar processes can be used to control partial parameters other than amplitude. One of skill in the art would also understand that similar processes as described above can be used to control the behaviour of partial parameters for other types of commands such as off-trigger commands.

Using descriptors as explained above provides the user 204 with a lot of control over the behaviour of a sound, as it evolves over time. Additive synthesis allows for each partial to behave uniquely with respect to its peer partials, leading to a broad range of sounds not available through other techniques such as subtractive synthesis. The user is free to generate envelopes for each partial in a form corresponding to standard on-trigger commands such as the MIDI On-Note command, or add additional stages that provides more texture and detail to an evolving timbre.

Furthermore, the entry of a large amount of control data to manipulate the partial parameters is simplified by use of touchscreens and GUIs, as described in the embodiment above. This is a huge advantage over the prior art, which did not contemplate the use of touchscreens and GUIs to enter a large amount of control data.

In other embodiments, a user can save the data relating to their designs using patch files in a storage medium such as an SD card. These files describe the high-level behaviour of the envelopes over time. In some embodiments, the patch files also store other coarse level control data such as frequency spacing and rolloff parameters in addition to the descriptors. An example embodiment of saving and loading patches is shown in Section 10 on page 63 of the Draft User Manual. Another example embodiment using USB is shown in Section 11 on page 64 of the Draft User Manual.

In some embodiments, the control processor 221 expands the reference points into more detailed values prior to storage in descriptor tables 207 in control subsystem storage 211. The speed of retrieval of values from descriptor tables 207 by waveform read control subsystem 305 is based on a ‘tempo’ or ‘retrieval rate’ frequency setting. The retrieval rate setting is set by the user using, for example, one of input devices 202 such as a potentiometer, and the retrieval rate is less than the audio sample rate. In some embodiments, the retrieval rate is one or more orders of magnitude less than the audio sample rate. For example, the retrieval rate is one-tenth (1/10th), or one-hundredth (1/100th); or one-thousandth (1/1000th) of the audio sample rate. Then, waveform read subsystem 305 interpolates values between the retrieved values for each partial in each oscillator so that the output channel can operate at the higher audio sample rate. Examples of interpolation comprise linear interpolation, polynomial interpolation and spline interpolation. This is made possible by the highly parallelized nature of the FPGA architecture, which enables complex calculations such as interpolation on a per partial basis.

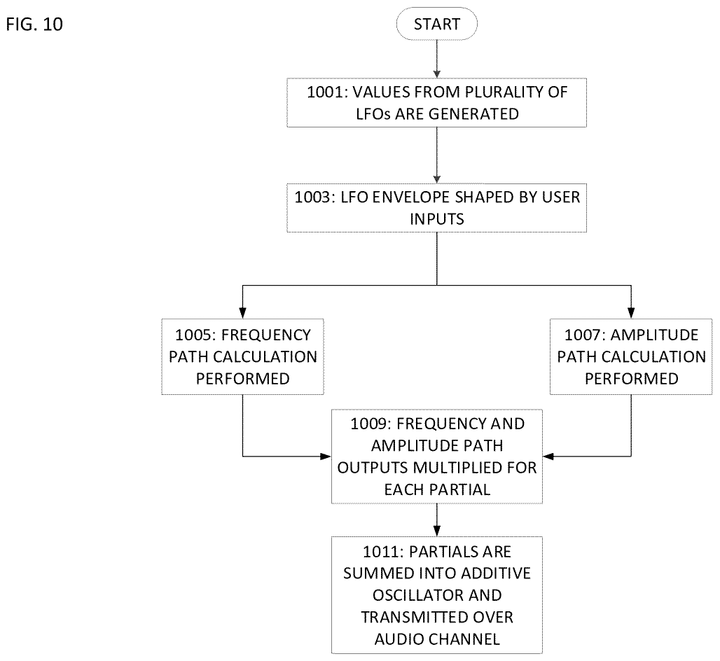

As explained previously, data read or fetched from the descriptor table 207 by waveform read control subsystem 305 is sent to the oscillator generation subsystem 309 and is used to control the behaviour of the additive oscillators. A process is described below and with reference to FIGS. 8 and 10 to produce audio output signals using the above read data from the descriptor table 207.

In step 801, a trigger signal for waveform read control subsystem 305 is generated, based on, for example, an on-trigger signal received from controller 123, such as a MIDI Note On command. This received on-trigger signal is decoded and parsed by one or more of management subsystem 209 and control processor 221, to generate a trigger signal for waveform read control subsystem 305. This includes, for example, reading the status fields as described previously, and generating triggers containing the information within these status fields. As explained previously, the generated trigger signal is then transmitted to waveform read control subsystem 305.

In step 803, the waveform read control subsystem 305 of FIG. 2 receives the generated trigger signal, and initiates the issue of read requests. The waveform read control subsystem 305 transmits the issued read requests to the on-trigger descriptor tables 207 in control subsystem storage 211 via overall interconnections 105, as explained previously. As explained above, the waveform read control subsystem 305 performs these functions based on pointers communicated by the management subsystem 209 via overall interconnections 105 to waveform read control subsystem 305.

In step 805, the descriptor data containing the partial parameter envelopes data for the current time offset from the trigger event is retrieved from descriptor tables 207 and then sent to oscillator generation subsystem 309 via overall interconnections 105. In some embodiments, step 805 comprises the descriptor data being sent to the waveform read control subsystem 305 after retrieval from the descriptor tables 207 before being sent to oscillator generation subsystem 309. In some embodiments, step 805 comprises the waveform read control subsystem 305 interpolating values based on the tempo or retrieval rate setting as explained above.

In some of the embodiments where ADSR stages are used, step 805 comprises the following: When a user plays a key on controller 123 to produce a sound, and does not release the key, the waveform read control subsystem 305 moves through the envelope descriptor for each partial. When the waveform read control subsystem 305 reaches the Release stage of the envelope, as long as the user does not release the key on controller 123, the waveform read control subsystem 305 will jump back to the Sustain stage on the time screen. That is, the waveform read control subsystem 305 loops the descriptor envelopes between the Sustain and Release portions of the envelopes. Upon controller key release, the envelope descriptors will jump to the Release stage of the envelope, and the amplitude fades away.

In some embodiments, step 805 comprises the waveform read control subsystem 305 performing further modifications on the data received from the descriptor tables 207 prior to being sent on to oscillator generation subsystem 309. As previously explained, control variables within the waveform read control subsystem 305 to modify descriptor read data and other control variables are updated as status information is received over MIDI. Examples of these control variables include, for example, aftertouch, as previously described. Then, as previously disclosed, the waveform read control subsystem 305 uses these control variables to further modify the data received from the descriptor tables 207 prior to being sent on to oscillator generation subsystem 309.

In step 807, using the processes described above, the oscillator generation subsystem 309 acts to generate each additive oscillator for transmission over an audio channel, from additive oscillator output subsystem 2C-13.

FIG. 10 shows an example embodiment of a process to generate an additive oscillator for transmission over an audio channel in step 807. Turning to FIG. 10, in step 1001, values from the plurality of LFOs in the LFO module 2C-09 in FIG. 2C are generated as previously explained. For example, with reference to the arrangement shown in the Draft User Manual, the values from the AM, FM, APA, APB, APC, FPA, FPB and FPC LFOs are obtained, as previously explained.

In step 1003, the values obtained from LFO module 2C-09 are shaped within the LFO envelope module 2C-11 based on user inputs applied to this module, as previously explained.

In steps 1005 and 1007, the frequency path and amplitude path calculations are performed in parallel in frequency path module 2C-05 and amplitude path module 2C-07, as previously explained.

In step 1009, the outputs from steps 1005 and 1007 are multiplied for each partial in multiplication block 2C-15 of additive oscillator output block 2C-13 as described previously.

In step 1011, the outputs from all the partials are summed in summation block 2C-17 of additive oscillator output block 2C-13 to form an additive oscillator, which is then sent out in an audio channel 2C-19 as described previously. This process is repeated for all the additive oscillators used to generate the sound.

In step 809, the output audio channels generated from the additive oscillator output subsystem 2C-13, are transmitted to waveform mixing subsystem 315 over waveform subsystem interconnections 313 for mixing, as described previously. The waveform mixing subsystem 315 of FIG. 2 performs appropriate mixing operations as previously described to generate one or more mixes as required. Each of these one or more mixes are then output over one or more audio channels from the waveform mixing subsystem 315.

In some embodiments, in step 811 at least one of the one or more mixes output from waveform mixing subsystem 315 are transmitted to waveform effects subsystem 313 for addition of effects, as described previously. Once effects are added, at least one of the one or more effect-enhanced mixes are transmitted to output interface 307 over waveform subsystem interconnections 313 as TDM signals.

In step 813, output interface 307 receives the TDM signals from waveform subsystem interconnections 313, produces, and transmits output signals 109 as described above.

One of ordinary skill in the art would understand that the process presented in FIG. 8 is but one example embodiment of a process to produce output signals 109, and that there are variations to the above process. For example, in some embodiments, step 811 is performed after step 807 and prior to step 809 for some audio channels. That is, the output audio signals which are generated by oscillator generation subsystem 309, are sent to waveform mixing subsystem 315 where effects are added. After addition of the effects, the enhanced signals are then mixed prior to being sent to output interface 307 via waveform subsystem interconnections 313.

As explained above, additive resynthesis can also be performed, whereby a reference audio input is rebuilt from constituent frequencies. In some embodiments, modifications are performed as part of the rebuilding process. An embodiment of a process for additive resynthesis is described in FIG. 9.

In step 901, input interface 301 of waveform subsystem 101 acts to receive reference audio input 353 from reference audio source 351, as described above.

In step 903, waveform subsystem 101 enters resynthesis mode, and signals based on the received reference audio input are transmitted by input interface 301 via waveform subsystem interconnections 313 to FFT subsystem 303 of FIG. 2.

In step 905, as was previously described above: FFT subsystem 303 generates output signals comprising in-phase (I) and quadrature (Q) components of multiple frequency bins, and transmits these generated output signals to resynthesis engine 203 of control subsystem 103 via, for example overall interconnections 105.

In step 907, resynthesis engine 203 analyzes the frequency content of the FFT subsystem output signal produced by the FFT subsystem 303 as described above.

In step 909, resynthesis engine 203 generates descriptor envelopes. Then, the resynthesis engine 203 together with, for example, control processor 221 populates descriptor tables 207 with these generated descriptor envelopes. As explained previously, the management subsystem 209 informs the resynthesis engine 203 and control processor 221 of the addresses associated with descriptor tables 207 in control subsystem storage 211, so that the descriptor tables 207 are populated.

In some embodiments, in step 911, user 204 modifies the generated descriptor envelopes using, for example, the one or more GUIs. User 204 performs this by providing user inputs 206 to input devices 202. Then, the resynthesized signal will be a modified version of the original reference audio input.

In step 913, the generated descriptor envelopes are used to control additive oscillators. Then, the generated descriptor envelopes are read from the descriptor tables 207 using, for example, the circular buffer approach previously described above. Once the descriptor envelopes have been read, they are transmitted from the descriptor tables 207 to oscillator generation subsystem 309 via overall interconnections 105 for generation of additive oscillators and output audio channels. Processes to generate additive oscillators have been described previously. In some embodiments, during entry into resynthesis mode, the additive oscillators such as additive oscillator 2B-01 of FIG. 2B are appropriately configured such that the spacing between each partial oscillator aligns with the bin bandwidth from the FFT subsystem 303. Then, the generated descriptor envelopes are applied in real time to the partial oscillators.

Processes to generate output signals 109 using audio channels output from oscillator generation subsystem 309 have been explained previously in, for example, steps 809, 811 and 813 of FIG. 8.

As explained previously, there are many possible ways to implement the above-described embodiments. For example, in some embodiments, the controller 123 is external to system 100. In other embodiments, controller 123 is implemented within a sequencer which is part of control subsystem 103, and can be controlled via an input device 202 such as a touch screen.

In other embodiments, either one or more of waveform subsystem 101 and control subsystem 103 are implemented in a distributed fashion. In yet other embodiments, some elements of control subsystem 103, for example, input devices 202, one or more displays 201 and one or more GUIs 205; are implemented as an application or an “app” on a device such as a laptop, desktop, tablet or smartphone coupled to the rest of control subsystem 103 via a network. In yet other embodiments, system 100 is implemented using a cloud-based implementation.

Although the algorithms described above including those with reference to the foregoing flow charts have been described separately, it should be understood that any two or more of the algorithms disclosed herein can be combined in any combination. Any of the methods, algorithms, implementations, or procedures described herein can include machine-readable instructions for execution by: (a) a processor, (b) a controller, and/or (c) any other suitable processing device. Any algorithm, software, or method disclosed herein can be embodied in software stored on a non-transitory tangible medium such as, for example, memory devices or other memory technologies known to those of skill in the art. Persons of ordinary skill in the art will readily appreciate that the entire algorithm and/or parts thereof could alternatively be executed by a device other than a controller. Also, some or all of the machine-readable instructions represented in any flowchart depicted herein can be implemented manually as opposed to automatically by a controller, processor, or similar computing device or machine. Further, although specific algorithms are described with reference to flowcharts depicted herein, persons of ordinary skill in the art will readily appreciate that many other methods of implementing the example machine readable instructions may alternatively be used. For example, the order of execution of the blocks may be changed, and/or some of the blocks described may be changed, eliminated, or combined.

It should be noted that the algorithms illustrated and discussed herein as having various modules which perform particular functions and interact with one another. It should be understood that these modules are merely segregated based on their function for the sake of description and represent computer hardware and/or executable software code which is stored on a computer-readable medium for execution on appropriate computing hardware. The various functions of the different modules and units can be combined or segregated as hardware and/or software stored on a non-transitory computer-readable medium as above as modules in any manner, and can be used separately or in combination.

While particular implementations and applications of the present disclosure have been illustrated and described, it is to be understood that the present disclosure is not limited to the precise construction and compositions disclosed herein and that various modifications, changes, and variations can be apparent from the foregoing descriptions without departing from the spirit and scope of an invention as defined in the appended claims.

What is claimed is:

1. A system to generate audio output signals comprising:
a control subsystem coupled to a waveform subsystem via one or more first interconnections, wherein:
the control subsystem comprises:
a control processor,
a management subsystem, and
a control subsystem storage storing one or more descriptor tables, further wherein:
the control processor, the management subsystem and the control subsystem storage are communicatively coupled to each other via one or more control subsystem interconnections;
the waveform subsystem is implemented using field programmable gate arrays (FPGAs), wherein the waveform subsystem comprises:
an oscillator generation subsystem,
a waveform read subsystem, and
an output interface, further wherein:
the oscillator generation subsystem, the waveform read subsystem and the output interface are communicatively coupled to each other via one or more waveform subsystem interconnections;
one or more of the management subsystem and the control processor generates and transmits a trigger signal to the waveform read control subsystem;
in response to the transmitted trigger signal, the waveform read control subsystem transmits read requests to the control subsystem storage to retrieve a plurality of descriptors stored in the descriptor tables via the first set of interconnections;
based on the transmitted read requests, the plurality of descriptors are:
retrieved from the control subsystem storage, and
transmitted to the oscillator generation subsystem via the first set of interconnections;
the oscillator generation subsystem:
generates an additive oscillator, further wherein:
the additive oscillator is generated based on a plurality of partial oscillators, and
the plurality of partial oscillators is generated based on the transmitted plurality of descriptors, and
transmits the generated additive oscillator to the output interface via an audio channel; and
the output interface receives the transmitted additive oscillator and generates the audio output signals based on the received additive oscillator.

2. The system of claim 1, wherein:
a controller is communicatively coupled to the control subsystem; and
the trigger signal is generated by the one or more of the management subsystem and the control processor based on a command or a trigger sent by the controller.

3. The system of claim 1, wherein the FPGAs are programmed from boot code stored on a boot storage communicatively coupled to the waveform subsystem.

4. The system of claim 3, wherein the boot code is updated using firmware updates.

5. The system of claim 1, wherein
a rate of retrieval of the plurality of descriptors is based on a retrieval rate setting;
an audio sample rate associated with the audio channel is higher than the rate of retrieval; and
the waveform read control subsystem interpolates values between values associated with the plurality of retrieved descriptors to enable the audio channel to operate at the sample rate.

6. The system of claim 1, wherein:
the plurality of partial oscillators comprises a first partial oscillator;
the oscillator generation subsystem comprises a frequency path module and amplitude path module;
the first partial oscillator is generated using:
a frequency path calculation performed by the frequency path module, and
an amplitude path calculation performed by the amplitude path module, further wherein:
the frequency path calculation and the amplitude path calculation are performed in parallel.

7. The system of claim 1, wherein:
the control subsystem further comprises:
a first input device and a second input device,
a first graphical user interface (GUI) displayed on a first display,
a second GUI displayed on a second display, further wherein:
the first input device, the second input device, the first display and the second display are communicatively coupled to each other and to the control processor, the management subsystem, and the control subsystem storage via the control subsystem interconnections; and
the control processor generates the plurality of descriptors, wherein the generating comprises:
the first GUI generating a stage curve on the first display in response to the user entering a first set of inputs using the first input device, and
the second GUI generating a partial parameter curve on the second display in response to the user entering a second set of inputs using the second input device.

8. The system of claim 1, wherein:
the waveform read control subsystem is provisioned by the management subsystem with at least one base pointer address to the descriptor tables.

9. The system of claim 1, wherein:
the waveform subsystem comprises an input interface and a fast Fourier transform (FFT) subsystem communicatively coupled to each other via the waveform subsystem interconnections;
the control subsystem comprises a resynthesis engine communicatively coupled to the control subsystem storage via control subsystem interconnections;
the input interface transmits a signal based on a reference audio input to the FFT subsystem;
the FFT subsystem generates output signals based on the reference audio input;
the FFT subsystem transmits the generated output signals to the resynthesis engine; and
the resynthesis engine generates the plurality of descriptors based on the output signals transmitted from the FFT subsystem.

10. The system of claim 6, wherein:
the oscillator generation subsystem comprises a summation block; and
the additive oscillator is generated by the summation block based on a summation of the plurality of partial oscillators.

11. A method to generate audio output signals, wherein:
a control subsystem is communicatively coupled to a waveform subsystem, further wherein the waveform subsystem is implemented using field programmable gate arrays (FPGAs);
the method comprising:
responsive to a trigger signal, transmitting, by the waveform subsystem, read requests to retrieve a plurality of descriptors from the control subsystem;
transmitting, by the control subsystem to the waveform subsystem, the retrieved plurality of descriptors;
generating an additive oscillator, wherein
the additive oscillator is generated based on a plurality of partial oscillators, and
the plurality of partial oscillators is generated based on the transmitted plurality of descriptors; and
generating the audio output signals based on the generated additive oscillator.

12. The method of claim 11, comprising generating, by the control subsystem, the trigger signal.

13. The method of claim 11, wherein
a rate of retrieval of the plurality of descriptors is based on a retrieval rate setting;
an audio sample rate associated with the audio channel is higher than the rate of retrieval; and
the method comprises:
interpolating values between the values associated with the plurality of retrieved descriptors to enable the audio channel to operate at the audio sample rate.

14. The method of claim 11, wherein
the plurality of partial oscillators comprises a first partial oscillator;
the method further comprising:
generating the first partial oscillator based on performing a frequency path calculation and an amplitude path calculation in parallel.

15. The method of claim 14, wherein
the frequency path calculation and the amplitude path calculation are performed in real-time on a per sample basis.

16. The method of claim 14, wherein the frequency path calculation and the amplitude path calculation are based on a plurality of values output from a plurality of low frequency oscillator envelope calculations.

17. The method of claim 14, wherein the frequency path calculation and the amplitude path calculation are based on coarse controls.

18. The method of claim 14, wherein the amplitude path calculation is based on inputs to either enable or disable each of the plurality of partial oscillators.

19. The method of claim 11, comprising:
generating, by an FFT subsystem, an FFT output based on a received reference audio signal; and
generating, by a resynthesis engine, the plurality of descriptors based on the generated FFT output.

20. The method of claim 12, wherein the generating of the trigger signal is based on one or more signals sent by a controller.
